(19) United States
(12) Patent Application Publication
(10) Pub. No.: US 2026/0293231 A1
(43) Pub. Date: Sep. 24, 2026

(54) STRUCTURE WITH SPACER ADJACENT COLLECTOR AND RELATED METHODS

(71) Applicant: GlobalFoundries U.S. Inc., Malta, NY (US)

(72) Inventors: Jacob M. DeAngelis, Burlington, VT (US); Uppili S. Raghunathan, Essex Junction, VT (US); Sarah A. McTaggart, Essex Junction, VT (US); Megan Elizabeth Lydon-Nuhfer, Essex Junction, VT (US); Cameron Luce, Colchester, VT (US); Steven M. Shank, Jericho, VT (US); Vibhor Jain, Clifton Park, NY (US)

(21) Appl. No.: 19/086,225

(22) Filed: Mar. 21, 2025

(51) Int. Cl. H10D 62/10; H10D 10/01; H10D 10/40; H10D 10/80

(52) U.S. Cl. CPC H10D 62/115; H10D 10/051; H10D 10/40; H10D 10/821

(57) ABSTRACT

The disclosure provides a structure with a spacer adjacent a collector, and related methods. A structure of the disclosure includes a collector on a subcollector, an intrinsic base on an inner portion of the collector, and a spacer on an outer portion of the collector. A lower portion of the spacer horizontally abuts the intrinsic base.

### BACKGROUND

The present disclosure relates to bipolar transistor structures and methods to form such structures.

Internet-of-Things (IOT) devices, wearable devices, smartphone processors, automotive electronics, and radio frequency integrated circuits (RFICs) (including millimeter wave (mmWave) ICs) can benefit from the inclusion of bipolar junction transistors (BJTs) because BJTs tend to have more drive and are generally considered better suited for analog functions than field effect transistors (FETs). BJTs are typically formed as vertical devices (e.g., with an in-substrate collector, a base including an intrinsic base region aligned above the collector region and extrinsic base regions on opposing sides of the intrinsic base region, and an emitter aligned above the intrinsic base region). In such vertical BJT structures, horizontal device scaling to increase the number of devices over a desired surface area can offer significant performance improvements for a device. However, corresponding changes in the fundamental device structure(s) in each transistor may be needed to realize the desired amount of scalability in manufacture.

### SUMMARY

The illustrative aspects of the present disclosure are designed to solve the problems herein described and/or other problems not discussed.

Embodiments of the disclosure provide a structure including: a collector on a subcollector; an intrinsic base on an inner portion of the collector; and a spacer on an outer portion of the collector, wherein the spacer horizontally abuts the intrinsic base.

Other embodiments of the disclosure provide a structure including: a collector on a subcollector; an intrinsic base on an inner portion of the collector; and a spacer on an outer portion of the collector and horizontally abutting the intrinsic base; a dielectric layer having a different material composition from the spacer, and a polysilicon layer on the dielectric layer and having a sidewall horizontally abutting the spacer.

Additional embodiments of the disclosure provide a method including: forming a collector on a subcollector; forming an intrinsic base on an inner portion of the collector; and forming a spacer on an outer portion of the collector, wherein the spacer horizontally abuts the intrinsic base.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view of a structure according to embodiments of the disclosure.

FIG. 2 depicts an expanded cross-sectional view of a structure according to embodiments of the disclosure.

FIG. 3 depicts a cross-sectional view of a structure according to further embodiments of the disclosure.

FIGS. 4-9 depict cross-sectional views of processes in methods to form a structure according to embodiments of the disclosure.

FIGS. 10-15 depict cross-sectional views of processes in methods to form a structure according to further embodiments of the disclosure.

It is noted that the drawings of the disclosure are not necessarily to scale. The drawings are intended to depict only typical aspects of the disclosure and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides a structure with a spacer adjacent a collector, and related methods. A structure of the disclosure includes a collector on a subcollector, an intrinsic base on an inner portion of the collector, and a spacer on an outer portion of the collector. A lower portion of the spacer horizontally abuts the intrinsic base. An extrinsic base is over the intrinsic base and the spacer, and horizontally between an upper portion of the spacer and the intrinsic base.

Bipolar junction transistor (BJT) structures, such as those in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may be contingent on the type and magnitude of bias applied to the material composition of one or both terminals, which affects the size of the potential barrier. In the case of a junction between two semiconductor materials, the potential barrier will be formed along the interface between the two semiconductor materials. Generally, a BJT structure includes a base region vertically or horizontally between emitter and collector materials. A BJT can be either a PNP-type BJT or an NPN-type BJT. In a PNP-type BJT, the emitter and collector regions have P-type conductivity and at least a portion of the base region has N-type conductivity. In an NPN-type BJT, the emitter and collector regions have N-type conductivity and at least a portion of the base has P-type conductivity. Additionally, it should be noted that, in a conventional BJT, the same semiconductor material (e.g., silicon) can be used for the base, collector and emitter. Alternatively, a BJT can be a heterojunction bipolar transistor (HBT). In a HBT, the collector and emitter are made, at least in part, of one semiconductor material (e.g., silicon) and the base is made, at least in part, of a different semiconductor material (e.g., silicon germanium). The use of differing semiconductor materials at the emitter-base junction and at the base-collector junction creates heterojunctions suitable for handling higher frequencies.

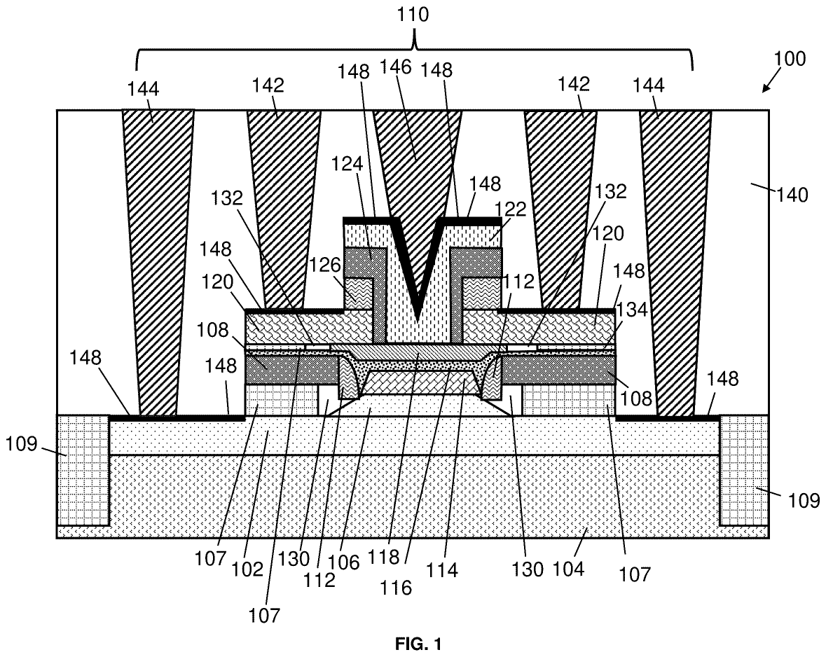

Referring to FIG. 1, a structure 100 according to the disclosure may include: a bipolar transistor (also abbreviated as a “BJT” to indicate “bipolar junction transistor,”) 110. Bipolar transistor 110 can, optionally, be a heterojunction bipolar transistor (HBT). In any case BJT can be, e.g., a vertically oriented bipolar transistor as discussed herein, in which spacers are located on a portion of a collector and extend vertically upward above the collector. The collector, as well as an intrinsic base thereover, may be horizontally within the spacers. In some implementations, the intrinsic base may extend horizontally beyond the collector and also may overlie an extrinsic base layer. Structure 100 may be formed on a subcollector 102 (i.e., a doped portion of a semiconductor substrate) including, e.g., one or more monocrystalline semiconductor materials. Subcollector 102 may include but is not limited to silicon, germanium, silicon germanium (SiGe), silicon carbide, or any other common integrated circuit (IC) semiconductor substrates. In the case of SiGe, the germanium concentration in subcollector 102 may differ from other SiGe-based structures described herein. A portion or entirety of subcollector 102 may be strained. Subcollector 102 may be doped (i.e., it may define a “doped well”), e.g., to enable coupling to the lower active semiconductor materials of a vertical bipolar transistor. Subcollector 102 may have any conceivable doping type and/or doping composition appropriate for use within and/or coupling to the collector terminal of a bipolar transistor. For instance, subcollector 102 may have the same dopant type as a collector 106 formed thereon, e.g., P-type doping in the case of a PNP-type BJT or N-type doping in the case of an NPN-type BJT, and/or may have a higher or lower dopant concentration therein.

Collector 106 may be on subcollector 102, e.g., as a single layer or multiple similarly doped but distinct layers formed by epitaxial deposition of silicon, SiGe, and/or other semiconductor materials on subcollector 102. Collector 106 may have a predetermined doping type, e.g., by being doped in-situ or during formation of semiconductor material(s) of subcollector 102 and/or subcollector 102. Collector 106 also may be monocrystalline in structure. Collector 106 may define active semiconductor material of a vertical bipolar transistor and thus may be vertically below other terminals (i.e., base, including extrinsic and intrinsic base regions, and emitter terminals discussed herein) of bipolar transistor 110. Collector 106 is illustrated as having inwardly tapered sidewalls over subcollector 102. However, collector 106 may have other shapes (e.g., curved sidewalls, tapered sidewalls, non-linear sidewalls, etc.) as a result of varying manufacturing techniques.

Structure 100 includes a set of dielectric layers, specifically a first dielectric layer 107 and a second dielectric layer 108 thereover, on subcollector 102 for additional electrical and physical separation of bipolar transistor 110 from other components. A lower portion of one first dielectric layer 107 may be horizontally adjacent a respective side of collector 106, and/or may horizontally surround collector 106 outside the cross-section shown. Although any number of dielectric layers 107, 108 may be present, two are shown as an example. According to an example, first dielectric layer 107 on subcollector 102 may be one or more oxide-based insulators (e.g., silicon dioxide (SiO₂) and/or other combinations of silicon and oxygen in different proportions), or other materials having similar properties. Second dielectric layer 108 on first dielectric layer 107 may be one or more nitride-based insulators (e.g., silicon nitride (SiN) and/or other combinations of silicon and nitrogen in different proportions) or other materials having similar properties but other combinations are possible. In some cases, only one dielectric layer (i.e., only one of layer 107 or layer 108) may be present, and/or additional layers may be present to provide an oxide-nitride-oxide (ONO) stack or other combination of insulative materials on subcollector 102.

However embodied, dielectric layer(s) 107, 108 may extend above subcollector above the height of collector 106 over subcollector 102. Dielectric layers 107, 108 optionally may also be horizontally alongside portions of a semiconductor film 116 on collector 106. Dielectric layers 107, 108 may be formed, e.g., by deposition of desired material(s) on subcollector 102, such as those in trench isolations (TIs) 109 adjacent subcollector 102, etc. Depending on the shape of dielectric layer(s) 107, 108, collector 106 when formed may have a tapered or tapered shape, e.g., with tapered sidewalls. In cases where collector 106 has inwardly tapered sidewalls, various materials on collector 106 (e.g., intrinsic base 114 discussed herein) also may have tapered sidewall profiles, e.g., by selective epitaxial growth of additional material on collector 106.

Structure 100 also may include trench isolations (TIs) 109, which optionally may be subdivided into multiple layers and/or materials of varying width and/or depth, and may also be on subcollector 102 to horizontally separate various active semiconductor materials on substrate 104. As shown, some TIs 109 may extend vertically into substrate 104, whereas others may be located on subcollector 102 to prevent electrical shorting between subcollector 102 and overlying areas of bipolar transistor 110. As discussed elsewhere herein, TI 109 initially may extend over substrate 104 as a single layer. Portions of TI 109 may be removed to form a trench, which may undercut certain remaining portions of TI 109 near subcollector 102. The undercut portions of TI 109 may form substantially triangular divots, recesses, etc.

Embodiments of the disclosure include a set of spacers 112 on collector 106, e.g., over outer horizontal portions or ends thereof. Each spacer 112 spans from collector 106 to either or both of dielectric layers 107, 108. Each spacer 112 may be provided to limit the size of collector 106 as it is grown over subcollector 102, e.g., to prevent collector 106 from being vertically larger than dielectric layer(s) 107, 108. Limiting the size of collector 106, in turn, allows greater control over the transistor's electrical properties (“tunability”) without otherwise significantly changing the manufacturing process(es) to form a vertical bipolar transistor. Spacer(s) 112 also physically isolate collector 106 and certain materials thereover (e.g., various intrinsic base materials) from dielectric layer(s) 107, 108 and allow desirable air gaps to be formed near collector 106. Spacers 112 may extend vertically upward from collector 106. An upper portion of collector 106, and an intrinsic base 114 thereover, may be horizontally enclosed within spacers 112.

Spacers 112 may include any currently known or later developed insulative material (e.g., those described herein relative to dielectric layer(s) 107, 108 and/or TI(s) 109), and more specifically may include non-semiconductor insulators formed with oxygen or nitrogen (e.g., aluminum oxide (Al₂O₃)). Spacers 112 have a different composition from dielectric layers 107, 108, e.g., to enable processing of dielectric layer(s) 107, 108 without affecting spacers 112. Thus, dielectric layers 107 can be etched, recessed, replaced, etc., while spacers 112 remain intact over collector 106. Spacers 112 may be free of semiconductor material(s) to better isolate collector 106 from other materials that border each spacer 112.

Bipolar transistor 110 may include a set of base materials including, collectively, an intrinsic base 114 on collector 106, semiconductor film 116 on intrinsic base 114 and adjacent (and/or horizontally between) spacers 112. Intrinsic base 114 may have a different composition and/or electrical properties but function in bipolar transistor 110 as a single terminal, whereby current applied to intrinsic base 114 controls the ability for current to flow between collector and emitter terminals of bipolar transistors 110. As illustrated, intrinsic base 114 extends vertically upward from collector 106 and partially adjacent spacer(s) 112 to create an upwardly protruding structure. Where collector 106 includes tapered, inwardly oriented sidewalls, intrinsic base 114 can have similarly shaped sidewalls such that a cross-section of intrinsic base 114 is substantially trapezoidal. Intrinsic base 114 thus may have a top surface that is narrower in horizontal width than the top surface of collector 106.

Intrinsic base 114 may include, e.g., monocrystalline silicon (Si), SiGe, or any other monocrystalline semiconductor material and may be relatively lightly doped to have a predetermined polarity. Intrinsic base 114 may include a different semiconductor material (e.g., silicon germanium as opposed to silicon) than collector 106 and an emitter 122 located thereover. The use of differing semiconductor materials at the emitter-base junction and at the base-collector junction creates heterojunctions, which are, for example, suitable for handling higher frequencies. In this case, the BJT is referred to in the art as an HBT as noted herein. In the case where the bipolar transistor is an NPN-type transistor and subcollector 102, collector 106, and emitter 122 are doped n-type, intrinsic base 114 may be doped p-type to form a P-N junction, and hence a base-to-collector interface. It is also understood that intrinsic base 114 may be doped n-type in the case where the bipolar transistor is a PNP-type transistor. However embodied, intrinsic base 114 may extend to a predetermined height over collector 106.

Bipolar transistor 110 also may include semiconductor film 116 on intrinsic base 114, and over a substantially larger width than that of intrinsic base 114. Semiconductor film 116 may be wider than intrinsic base 114 to enable deposition and growth of other semiconductor material(s) of different conductivity types elsewhere in the forming of bipolar transistor 110. Semiconductor film 116 may include, e.g., non-doped silicon (Si) or lightly doped silicon (Si) in various crystalline forms, e.g., single crystallographic orientation Si, polycrystalline Si, etc. In some implementations, semiconductor film 116 may be known as an “intrinsic semiconductor” material. As discussed herein, semiconductor film 116 may be formed by forming the material of intrinsic base 114 to a desired height before forming semiconductor film 116 thereon, and/or by removing a portion of intrinsic base 114 material for replacement with semiconductor film 116. Semiconductor film 116 may also be formed by any other currently known or later developed technique to form transitional semiconductor material suitable for subsequent forming of extrinsic base 120 and/or emitter 122 material thereon, having varying conductivity types and/or dopant concentrations. Semiconductor film 116 may function, electrically, as a part of the intrinsic base for bipolar transistor 110 but may have a different composition to function as an etch stop layer to control the location and size of emitter 122. Thus, singular references to the “intrinsic base” of bipolar transistor 110 may refer to intrinsic base 114 and semiconductor film 116, collectively.

Bipolar transistor 110 may include a emitter film 118 on a portion of semiconductor film 116. Emitter film 118, more specifically, may be on or physically proximate inner portions of semiconductor film 116 that overlie intrinsic base 114. Emitter film 118 may include, e.g., silicon having an opposite doping type from that of intrinsic base 114. Emitter film 118 thus may have the same doping type as subcollector 102 and collector 106 to define the PNP or NPN interfaces for bipolar transistor 110. Emitter film 118 may be formed by any currently known or later developed process to form and dope a semiconductor material, e.g., deposition, etching, and/or ion implantation. Emitter film 118, similar to collector 106, may include Si instead of SiGe to provide different compositions across the emitter-base interface, thus providing an HBT structure in bipolar transistor 110.

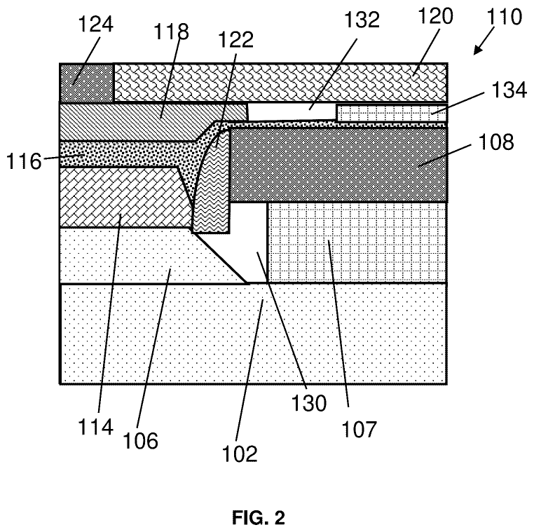

Extrinsic base(s) 120 on outer portion(s) of emitter film 118. Extrinsic base(s) 120 may include a polycrystalline semiconductor (e.g., polycrystalline SiGe) with a relatively high amount of the same doping type as (e.g., more p-type doping than) intrinsic base(s) 114, 116. Extrinsic base(s) 120 may be formed, e.g., by depositing an initial (seed) layer of monocrystalline and/or other semiconductor materials of emitter film 118. Extrinsic base(s) 120 may extend horizontally beyond emitter film 118, e.g., portions of extrinsic base(s) 120 may pass over an upper air gap 132 adjacent emitter film 118 (shown in more detail in FIG. 2 and discussed elsewhere herein). Additional portions of first dielectric layer 107 optionally may be formed on semiconductor film 116 over second dielectric layer 108 to provide additional insulation, and extrinsic base 120 may contact and overlie the additional portions of first dielectric layer 107 in this case. Through selective epitaxial growth, deposition, and/or other processing (such as doping), extrinsic base(s) 120 can be formed from the initial layer to a desired height. In some embodiments discussed herein, emitter film 118 may be absent, in which case extrinsic base(s) 120 may be formed directly on semiconductor film 116. Notwithstanding the alternate doping type in emitter film 118, the relatively small thickness of emitter film 118 compared to extrinsic base 120 and intrinsic base 114 allows extrinsic base(s) 120 to function as a base terminal in bipolar transistor 110.

Emitter 122 may be on the center portion of emitter film 118. In an example, portions of emitter 122 may be horizontally between portions of extrinsic bases 120 that extend horizontally outward from, and vertically above, emitter film 118. Emitter 122 may be formed on and above emitter film 118, e.g., by forming a stack of materials including portions of extrinsic base(s) 120, removing a portion of the stack of materials, and forming emitter 122 and/or other components within and/or in place of the removed extrinsic base 120 material. Emitter 122 may have the same doping type as subcollector 102 and collector 106, and thus, has an opposite doping type relative to extrinsic base 120 (and intrinsic base 114, if doped). In the case where bipolar transistor 110 is an NPN device, emitters 118, 122 may be doped n-type to provide the two n-type active semiconductor materials whereas intrinsic bases 114, 116 and extrinsic base 120 may be doped p-type. Emitter 122 may include polycrystalline silicon and/or other monocrystalline semiconductor materials, including one or more materials used elsewhere in structure 100 to form subcollector 102, collector 106, extrinsic base 120 (with different doping), etc. Emitter 122, in one example, may be polycrystalline by epitaxially growing silicon on emitter film 118 and horizontally within a set of inner spacers 124, 126, such that emitter 122 has multiple crystallographic orientations.

Structure 100 includes another set of spacers (e.g., an inner spacer 124 and an outer spacer 126) adjacent emitter 122. Inner spacer 124 may be alongside emitter 122, and outer spacer 126 may be alongside inner spacer 124 such that a portion of inner spacer 124 is horizontally between emitter 122 and outer spacer 126. Outer spacer 126 similarly may be horizontally between inner spacer 124 and extrinsic base 120. Spacers 124, 126 may vertically interface with an upper surface of emitter film 118 (e.g., on semiconductor film 116 thereof). Each spacer 124, 126 may have a different dielectric constant and thus may provide a distinct amount of electrical isolation, e.g., inner spacer 124 may include a nitride based insulator (such as a silicon nitride material) and outer spacer 126 may include an oxide based insulator (Such as a silicon oxide material) or vice versa. Other compositions and/or arrangements of spacers 124, 126 currently known or later developed also may be used. Spacer(s) 124, 126 together may include oxide materials, nitride materials, and/or any other insulative material discussed herein, e.g., compositions similar to dielectric layer(s) 107, 108, TI 109, or other insulating structures. In some implementations, spacer(s) 124, 126 may include a single layer or more than two layers. Spacers 124, 126 may have different compositions to control (e.g., increase) the electrical insulation between emitter 122 and extrinsic base 120.

Referring to FIGS. 1 and 2 together, in which FIG. 2 provides an expanded partial view of a portion of bipolar transistor 110, further insulative components of structure 100 are discussed. Portions of bipolar transistor 110 adjacent those shown in FIG. 2 are omitted from the expanded view solely for clarity of illustration (i.e., they are still present). Remaining space below spacer 112 and not filled by of the other portions of bipolar transistor 110 discussed herein, may form an air gap 130 horizontally between collector 106 and dielectric layer(s) 107, 108. In other implementations, portions of dielectric layer(s) 107, 108 may be removed (e.g., it may be undercut during etching as discussed herein) to form air gap 130 before collector 106 and intrinsic bases 114, 116 are formed.

Air gap 130 refers to a region of space surrounded by, and hence not filled with, solid materials such as collector 106, dielectric layers 107, 108, etc. Air gap 130 may be formed by any conceivable method to enclose and/or seal off a desired space to prevent additional materials from being formed therein. For instance, the horizontal space between collector 106 and dielectric layers 107, 108 below spacer 112 may be significantly less than that of the horizontal space between collector 106 and dielectric layers 107, 108. By forming semiconductor film 116 and/or emitter film 118 over collector 106 and spacer 112 (e.g., by conformal deposition and/or other processing techniques described herein), films 116, 118 will cover spacer 112 to prevent further deposition of materials below spacer 112. Air gap 130, alternatively known as a “cavity,” “gas dielectric,” and/or similar terms known in the art, thus may have a lower dielectric constant (i.e., it is less conductive) than nearby insulative materials such as dielectric layer(s) 107, 108 and spacer 112. Air gap 130 thus may be formed by any currently known or later developed process to create an insulative region of space not filled with dielectric materials and/or other components.

The shape of collector 106, spacer 112, and dielectric layers 107, 108 together define the shape of air gap 130. Spacer 112 may be formed on a horizontally outer portion of collector 106 (e.g., at the top of its tapered sidewall) such that a lower portion of intrinsic base 114 horizontally abuts spacer 112. Where air gap 130 is formed partially by undercutting first dielectric layer 107 below second dielectric layer 108, spacer 112 and second dielectric layer 108 together may define an upper surface of air gap 130 such that the upper surface of air gap 130 does not exhibit a linear profile. Spacer 112, by being formed on collector 106, may extend below the lower surface of second dielectric layer 108 to meet the tapered sidewall of collector 106. Spacer 112 may structurally isolate semiconductor film 116 from air gap 130.

Bipolar transistor 110, optionally, also may include upper air gap 132 over semiconductor film 116 and vertically between emitter film 118 and an overlying dielectric layer 134 located over semiconductor film 116. Overlying dielectric layer 134 may be compositionally similar or identical to first dielectric layer 107, e.g., overlying dielectric layer 134 may include oxide based insulators such as those including silicon and oxygen (e.g., silicon oxides). Upper air gap 132, when present, may be formed by depositing additional overlying dielectric layer 134 material over semiconductor film 116, etching and/or otherwise recessing portions of overlying dielectric layer 134 approximately over spacer(s) 112 and intrinsic base 114, and forming emitter film 118 on semiconductor film 116, e.g., by targeted epitaxial growth. The amount of epitaxial growth and/or deposition implemented in emitter film 118 may be controlled such that emitter film 118 only partially fills the space previously occupied by overlying dielectric layer 134, thus defining upper air gap 132.

Air gap 130 may span vertically from a lower portion horizontally between collector 106 and first dielectric layer 107 to an upper portion horizontally between spacer 112 and first dielectric layer 107. Upper air gap 132 may be over dielectric layers 107, 108 and adjacent emitter film 118. Air gap 130 thus may be entirely below second dielectric layer 108 and upper air gap 132, with second dielectric layer 108 defining the vertical boundary between air gaps 130, 132. Non-selective forming processes may cause spacer 112 material to extend completely from collector 106 to second dielectric layer 108. Air gaps 130, 132 may be desirable as further contributing to electrical isolation between extrinsic bases 120 and collector 106. Air gaps 130, 132 in particular may impede or prevent other physical interfaces from forming between extrinsic base 120 and underlying materials other than semiconductor film 116. In some implementations either or both of air gaps 130, 132 instead may be occupied by portions of isolation layer(s) 107, 108, 134 to maintain an insulative boundary between active materials in bipolar transistor 110.

Referring to FIG. 1, structure 100 may include an inter-level dielectric (ILD) layer 140 over TI 109, extrinsic bases 120, emitter 122, spacers 124, 126, etc. ILD layer 140 may include the same insulating material as TI 109 or may include a different electrically insulative material for vertically separating active materials from overlying materials, e.g., various horizontally extending wires or vias. ILD layer 140 and TI 109 nonetheless constitute different components, e.g., due to TI 109 being vertically between subcollector 102 and the various active components of structure 100. ILD layer 140 may be formed by deposition and/or other techniques to provide electrically insulating materials, and can then be planarized (e.g., using chemical mechanical planarization (CMP)), such that its upper surface remains above any active components formed on subcollector 102. One or more barrier layers (not shown) including, e.g., nitride-based dielectric materials (such as silicon nitride (SiN)) may be on ILD layer 140 to further separate bipolar transistor 110 from overlying materials and/or to enable certain portions of structure 100 to be formed and processed differently from each other to affect the shape of conductive contacts to bipolar transistor 110.

A set of base contacts 142 extending through ILD layer 140 may provide the vertical electrical coupling between each extrinsic base 120 and overlying metal wires and/or vias. Base contacts 142, notably, do not extend to intrinsic base 114, semiconductor film 116, and/or emitter film 118. Intrinsic base 114, semiconductor film 116, and emitter film 118 thus are coupled to base contacts 142 only through extrinsic base 120. Before ILD 140 is formed, some portions of extrinsic base 120 may be converted into a silicide layer 148 to improve conductivity between each base contact 142 and any portions of extrinsic base 120 thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 148 for electrically coupling semiconductor materials to any contacts formed thereon. Excess conductive material can then be removed using any now known or later developed solution, e.g., etching.

Structure 100 also includes an emitter contact 146 to emitter 122 and a collector contact 144 to collector 106 through subcollector 102. Each contact 146, 144 may also be coupled to emitter 122 or subcollector 102, respectively, through silicide layers 148 formed therein. Each contact 142, 144, 146 may also extend through ILD layer 140, thus electrically connecting active semiconductor material within subcollector 102 or emitter 122 to overlying metal wires, vias, etc., above structure 100. Contact(s) 142, 144, 146 optionally may be formed as part of a single operation, e.g., by removing portions of ILD layer 140 to form openings and filling the openings with metal to define each contact 142, 144, 146. One or more of contacts 142, 144, 146 may include refractory metal liners (not separately shown) on their sidewalls to impede or prevent electromigration degradation, shorting to other components, etc.

Some portions of subcollector 102, emitter 122, and extrinsic base 120 may be converted into a silicide layer 148 to improve conductivity between each contact 142, 144, 146 and any active material thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 148 for electrically coupling semiconductor materials to any contact(s) formed thereon. Excess conductive material can then be removed using any now known or later developed solution, e.g., etching.

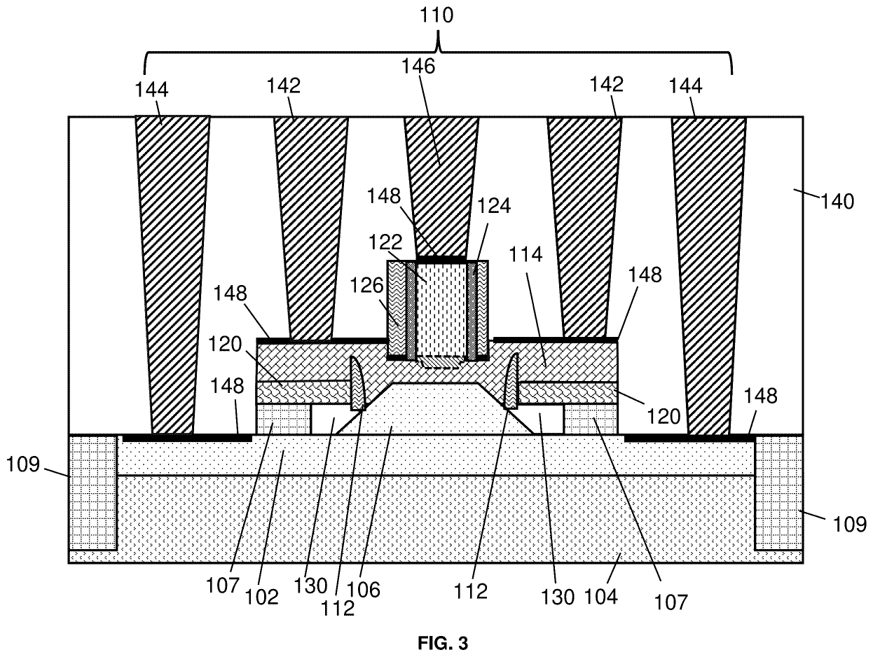

FIG. 3 depicts a further implementation of structure 100 where intrinsic base 114 and extrinsic base 120 are positioned differently from other embodiments herein, and where certain components (e.g., second dielectric layer 108, semiconductor film 116, emitter film 118 (shown with dashed lines in FIG. 3), additional air gap 132) are omitted. In such implementations, spacers 112 may be located on a portion of collector 106 adjacent air gap 130. However, intrinsic base 114 may be on collector 106 and spacers 112 such that intrinsic base 114 is vertically interposed between intrinsic base 114 and emitter 122. In this case, emitter film 118 may not be present or otherwise may be included vertically between intrinsic base 114 and emitter 122. Extrinsic base 120 may be on overlying dielectric layer 134 and may extend partially over air gap 130 such that extrinsic base 120 abuts an outer horizontal sidewall of spacer 112.

Spacer 112, by being on collector 106, can physically separate extrinsic bases 120 from collector 106 material, such that intrinsic base 114 forms the only electrical pathway between collector 106 and extrinsic bases 120. Air gap 130 also maintains electrical separation between collector 106 and extrinsic bases 120, e.g., by occupying the space below extrinsic base 120 and horizontally adjacent collector 106. Air gaps 130 may be formed by forming first dielectric layer 107 and extrinsic base 120 as a stack of layers, selectively etching a portion of first dielectric layer 107 to undercut extrinsic base 120 and forming collector 106 on subcollector 102 by epitaxial growth such that air gaps 130 remain present alongside collector 106. Spacer(s) 112 can then be formed on collector 106 before it is completely formed to prevent collector 106 from contacting extrinsic bases 120. In this configuration, base contacts 142 and silicide layers may be on intrinsic base 114 instead of being on extrinsic base 120. The presence of extrinsic base 120 vertically below intrinsic base 114 nonetheless may increase electrical conductivity in bipolar transistor 110 at the electrical interface between base contacts 142 and intrinsic base 114. In other respects, bipolar transistor 110 may be configured similarly to other embodiments discussed herein.

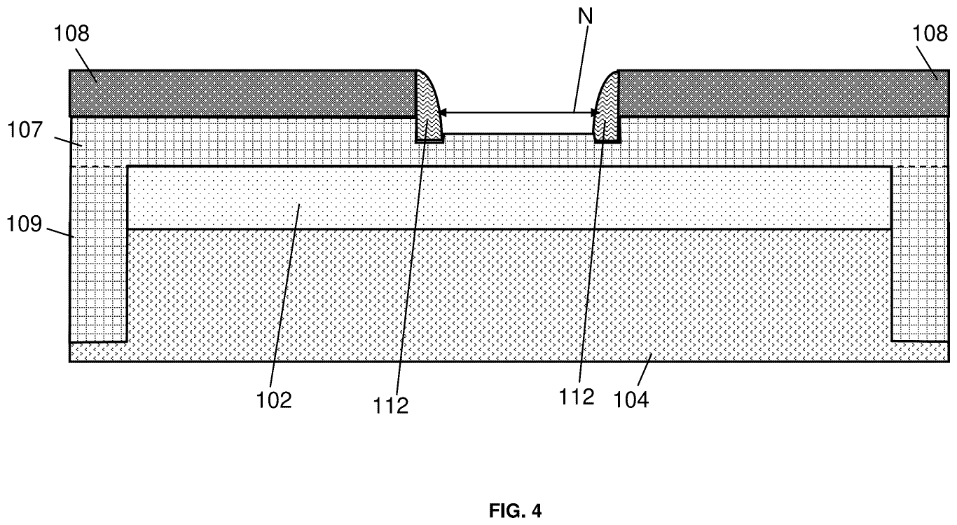

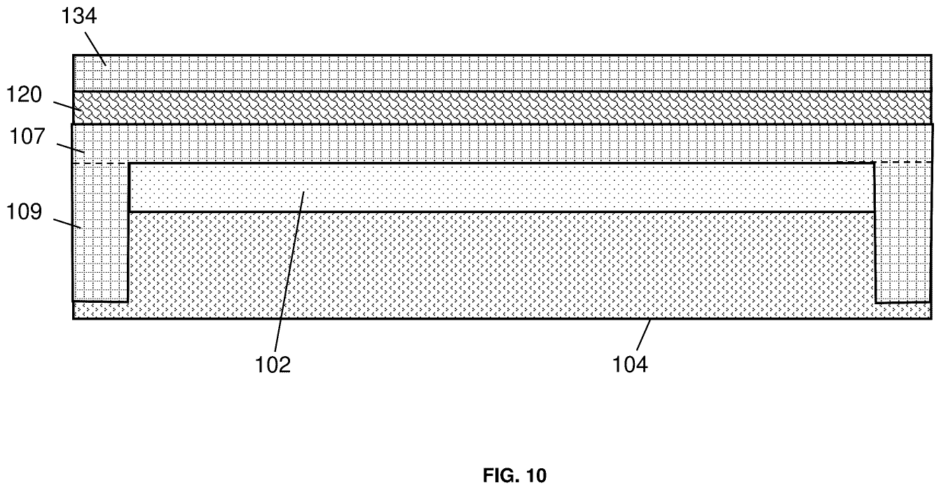

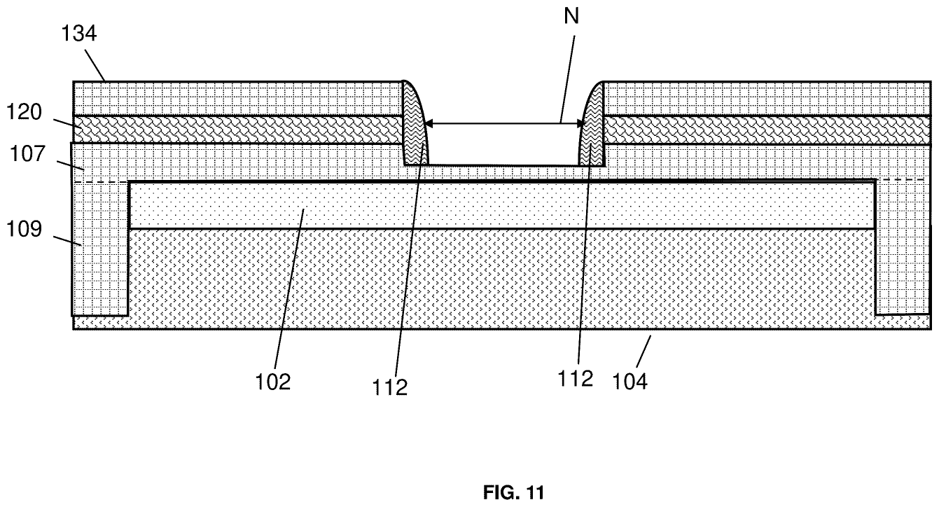

Turning now to FIG. 4, methods of forming structure 100 (FIGS. 1, 3) and bipolar transistor 110 (FIGS. 1-3) in various configurations are provided. Initial phases of processing may include forming subcollector 102 on substrate 104 (e.g., by targeted doping of semiconductor material to desired concentrations), forming TI(s) 109 and/or other isolating materials adjacent subcollector 102 and substrate 104, etc. Further processing may include forming dielectric layers 107, 108, 134 with TI(s) 109 on subcollector 102, e.g., by forming layers of insulating material on substrate 104 and subcollector 102 by deposition or other currently known or later developed techniques to provide insulator materials. In other configurations (e.g., to provide embodiments of structure 100 where extrinsic base 120 is on first dielectric layer 107), second dielectric layer 108 may be replaced with doped semiconductor material(s) suitable to form extrinsic base 120 (FIGS. 1-3). These processing configurations are depicted in FIGS. 10-15 and discussed elsewhere herein. First dielectric layer 107 and TI(s) 109 may be formed together as part of the same instance of deposition, in which case dielectric layer(s) 107 and TI(s) 109 may be structurally continuous in initial phases of processing.

An opening N can be formed within the deposited dielectric layer(s) 107, 108. Opening N may extend completely vertically through second dielectric layer 108 and only partially into first dielectric layer 107 as shown. Spacer(s) 112 can be formed by vertically depositing dielectric spacer material on exposed surfaces of dielectric layer(s) 107, 108 and then may be partially removed (e.g., by vertical) etch. The remaining dielectric material may create spacers 112 on opposite sidewalls of opening N.

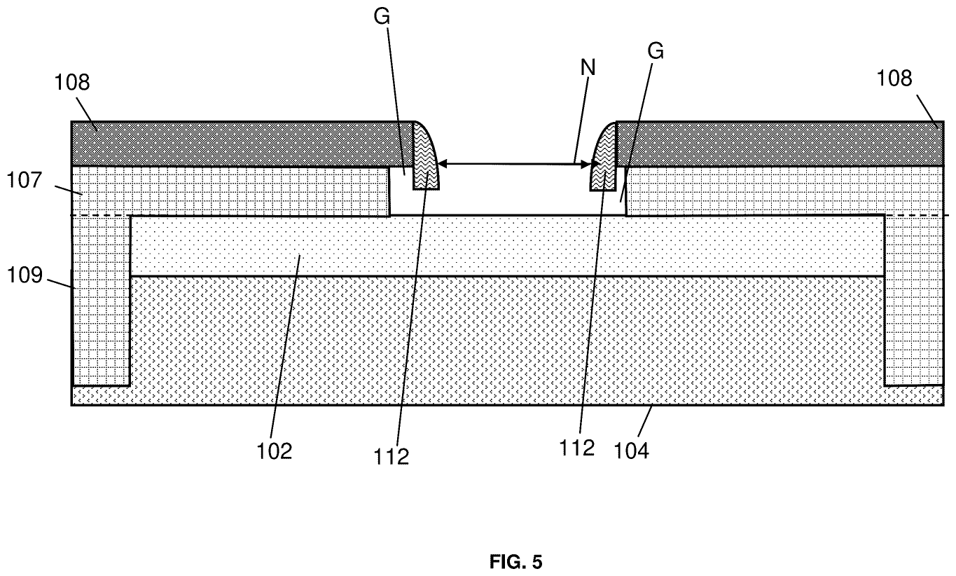

FIG. 5 depicts further processing to remove additional portions of first dielectric layer 107. The forming of opening N may produce undercut regions G beneath second dielectric layers 108. Undercut regions G, once formed, may enable air gaps (FIGS. 1-3) to be formed during subsequent processing to form collector 106 (FIGS. 1-3) of bipolar transistor 110. Undercut regions G may be formed from first dielectric layer 107 in a lower portion of opening N using an isotropic etch process. In this case, the isotropic etch process can be selective for first dielectric layer 107 so that further etching stops at subcollector 102 and also so that the etchant(s) undercut second dielectric layer 108, due to their different compositions. Thus, second dielectric layer 108 remains intact over the removed areas of first dielectric layer 107.

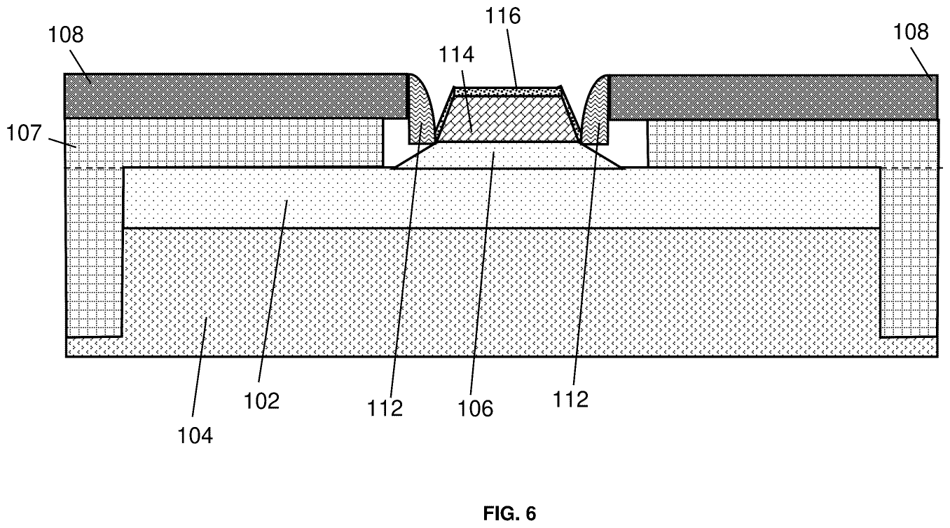

Referring now to FIG. 6, collector 106 can be formed within opening N, e.g., by epitaxial growth and doping of semiconductor material on subcollector 102 within opening N. In the case of forming by epitaxial growth, collector 106 may have sidewall shapes dependent on the shape of dielectric layer(s) 107, 108, the manner of growth implemented and/or the crystallographic orientation of subcollector 102 thereunder. Collector 106 may not completely horizontally fill opening N within dielectric layer(s) 107, 108, e.g., by controlling the amount of deposition time and/or etching back collector 106 material once it is formed.

Further processing may include, e.g., forming intrinsic base 114 as a monocrystalline semiconductor material on collector 106, horizontally between spacers 112. Intrinsic base 114 may be undoped or have an opposite doping type from collector 106, and in addition, may have a lower concentration of dopants therein. Optionally, intrinsic base 114 may have differently tapered and/or shaped sidewalls as a result of being formed near spacer 112. Collector 106 and/or intrinsic base 114 may be doped in situ during epitaxial deposition, or alternatively, through implantation and/or other currently known or later developed doping techniques. The forming of intrinsic base 114 may begin only after collector 106 is at a predetermined height relative to first dielectric layer 107 (e.g., between approximately half and all of the height of first dielectric layer 107 above subcollector 102).

Semiconductor film 116 may be formed on intrinsic base 114. An initial portion (e.g., a seed layer) of semiconductor film 116 may then be created by non-selective forming of, e.g., a layer of semiconductor material, doped during growth or after growth in situ to have the same conductivity as intrinsic base 114, with a different composition and/or crystallographic orientation on intrinsic base 114. Semiconductor film 116 may be formed on intrinsic base 114 without being formed on the surface of other components (e.g., second dielectric layer 108, spacers 112, etc.) through selective formation and/or deposition techniques. For instance, semiconductor film 116 may formed by conformal epitaxial growth of semiconductor material (e.g., crystalline Si) and subsequent doping by any conceivable process, e.g., by thermal anneal after semiconductor film 116 is formed. Semiconductor film 116 in the eventual bipolar transistor structure may function as a part of intrinsic base 114 but also may provide an etch stop layer to control the location and size of emitter film 118, as described in various embodiments herein.

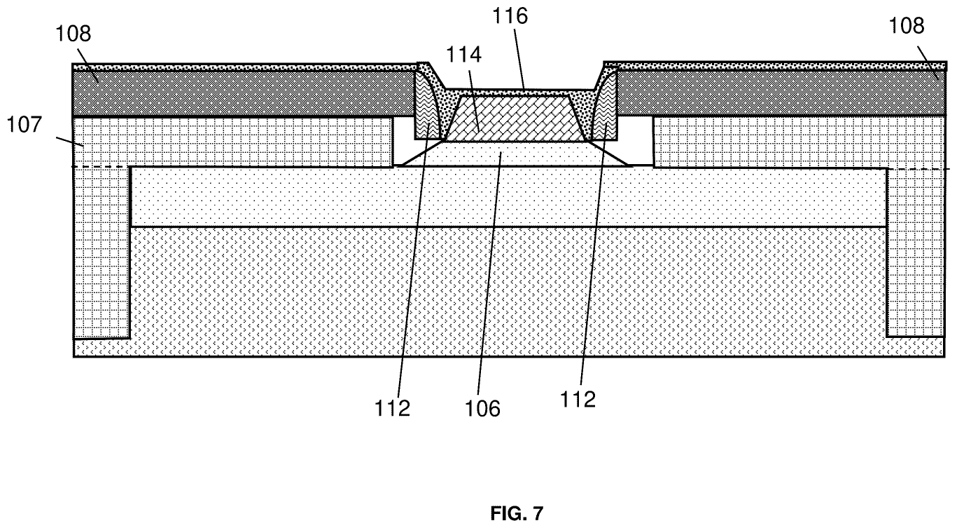

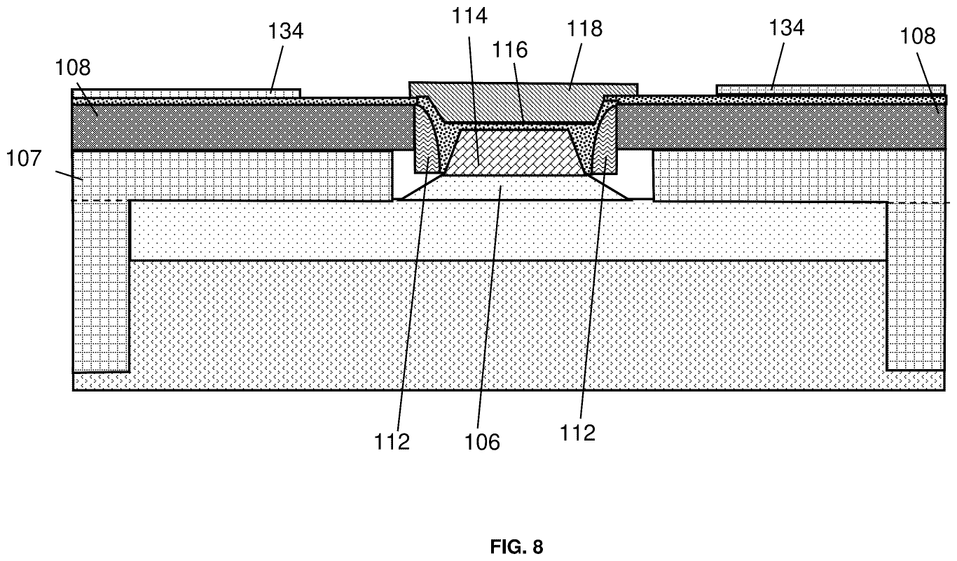

FIGS. 7 and 8 illustrate the forming of additional materials for connecting intrinsic base 114 to later formed active materials, particularly extrinsic base 120 and/or the emitter terminal of bipolar transistor 110 (FIGS. 1-3). FIG. 7 depicts a process to increase the size of semiconductor film 116, e.g., by continued epitaxial growth for semiconductor material(s) from the initial portion formed previously. Semiconductor film 116 thus may extend horizontally beyond spacers 120 to cover adjacent portions of second dielectric layer 108 and/or extrinsic base 120. Expanding of semiconductor film 116 size is optional and may not be implemented in certain implementations. FIG. 8 depicts forming emitter film 118 on semiconductor film 116, e.g., by deposition and subsequent etching with the aid of a mask (not shown). Emitter film 118, once formed, may be located over intrinsic base 114 but may not extend significantly horizontally beyond the location of spacers 112 to avoid interfering with the operation of extrinsic base(s) 120. In a similar manner (e.g., deposition, masking, and etching), overlying dielectric layers 134 may be formed on semiconductor film 116 in locations horizontally away from emitter film 118. Any horizontal separation between dielectric layer(s) 107 and emitter film 118 may define the position and shape of upper air gap(s) 132 (FIGS. 1-3) in the eventual structure of bipolar transistor 110.

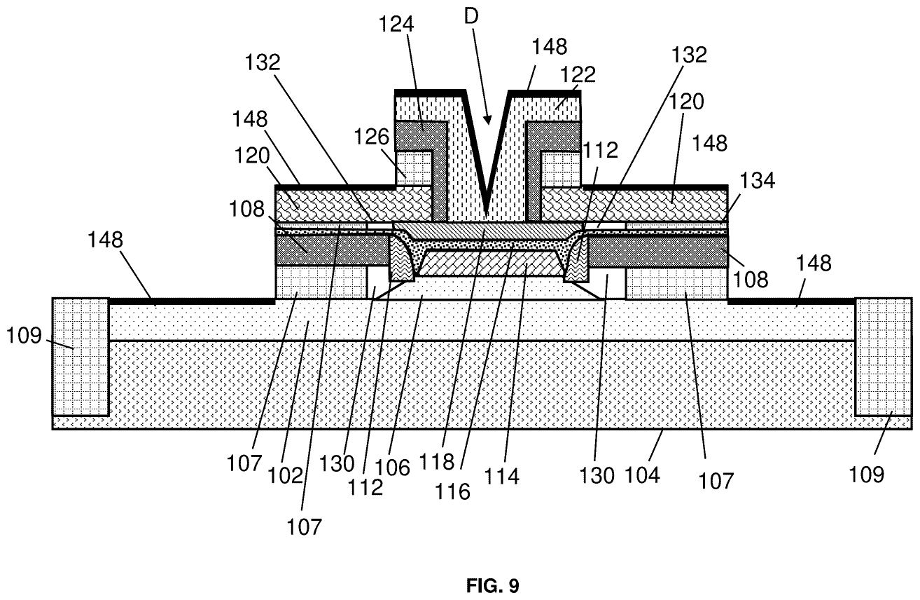

FIG. 9 depicts forming extrinsic base 120, emitter 122, and inner spacers 124, 126 on dielectric layers 134 and emitter film 118. These materials may be formed by application of conventional techniques to form emitter and base terminals of a transistor, and insulative material(s) therebetween. Extrinsic bases 120, for instance, may be formed by epitaxial growth, etching, and/or doping of polycrystalline silicon to create extrinsic bases 120 on outer portions of emitter film 118. The use of selective epitaxial growth may prevent extrinsic bases 120 from being formed in the space horizontally between emitter film 118 and dielectric layer(s) 134, thereby creating upper air gaps 132. One or more of inner spacers 124, 126 also can be formed by deposition, masking, and etching such that they are located horizontally alongside extrinsic base(s) 120. Spacer(s) 124, 126 may include at least one opening to emitter film 118. The opening(s) within spacer(s) 124, 126 can be filled with emitter 122, e.g., by additional selective epitaxial growth and doping of active semiconductor materials on emitter film 118. Emitter 122, optionally, may include a divot, cavity, and/or other partial opening D, in the case where emitter 122 material is formed by epitaxial growth of active semiconductor material on exposed surfaces of emitter film 118 and/or spacer(s) 124, 126.

Further processing may include forming silicide layers 148 on exposed areas of subcollector 102, extrinsic base(s) 120, and emitter 122. Silicide layers 148 may be formed by depositing one or more conductors (e.g., metal layers) on active semiconductor material, annealing the deposited metal to cause the deposited conductor(s) to migrate into the semiconductor material(s), and removing the excess conductor material(s). Thereafter, ILD 140 (FIG. 1) may be formed over substrate 104 and any components thereon. Openings may be formed within ILD 140 and filled with conductors to provide contact(s) 142, 144, 146 (FIG. 1) to yield bipolar transistor 110 (FIG. 1).

Referring now to FIG. 10, further methods to form bipolar transistor 110 (e.g., as depicted in FIG. 3) are also provided. In some cases, methods of the disclosure may not include second dielectric layer 108 (FIGS. 1, 2, 4-9) and instead may cause extrinsic base 120 to be formed before intrinsic base 114 (FIGS. 1, 2, 6-9). To provide such a structure, extrinsic base 120 may be on overlying dielectric layer 134. Extrinsic base 120 may have an opposite doping type from subcollector 102 and may have a relatively high amount of doping. Alternatively, extrinsic base 120 may not yet have significant doping and instead may be doped in later manufacturing stages. Initially, first dielectric layer 107 may be structurally continuous with TI(s) 109 as discussed elsewhere relative to other embodiments. An additional portion of first dielectric layer 107 may be over extrinsic base 120, such that extrinsic base 120 is vertically between two dielectric layers 107. The first dielectric layer 107 material on extrinsic base 120 may be partially or wholly removed in subsequent operations for replacement with intrinsic base material.

Similar to other methods discussed herein, an opening N may be formed within overlying dielectric layer 134, extrinsic base 120, and partially into first dielectric layer 107. Opening N may not extend completely vertically through dielectric layer 107, and thus the bottom of opening N initially may be above the upper surface of subcollector 102. The depth of opening N may be chosen by controlling the amount of etchants and/or etching time to form opening N, and the width of opening N may be chosen by forming a mask (not shown) on selected areas of overlying dielectric layer 134 and removing the mask after forming opening N. Spacers 112 then can be formed on sidewalls of opening N using any currently known or later developed process. Opening N may be formed by conformally depositing spacer 112 and thereafter vertically etching the deposited spacer 112 material such that spacers 112 remain intact only on sidewalls of opening N. Extrinsic bases 120 may be horizontally adjacent a vertically inner portion of an adjacent spacer 112, and thus the upper surfaces of spacers 112 are above extrinsic base 120 and the lower surfaces of spacers 112 may be below the lower surfaces of spacers 112.

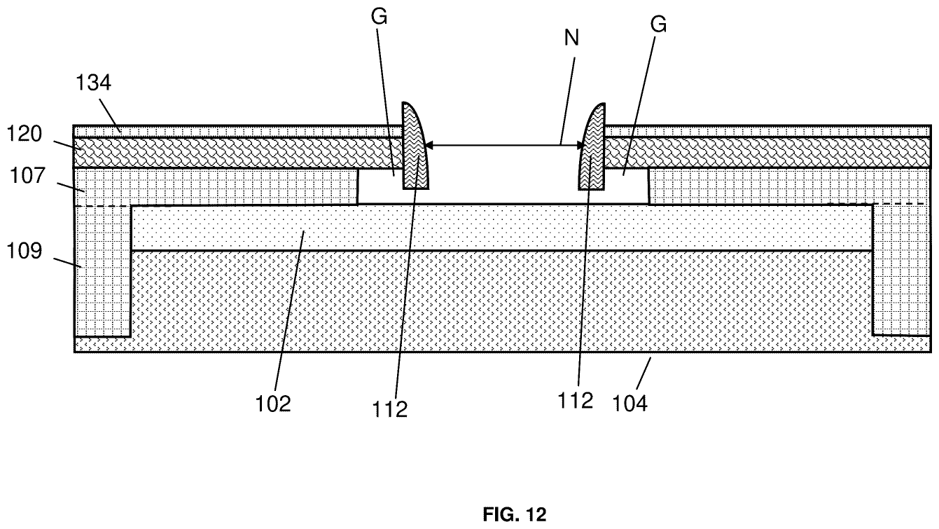

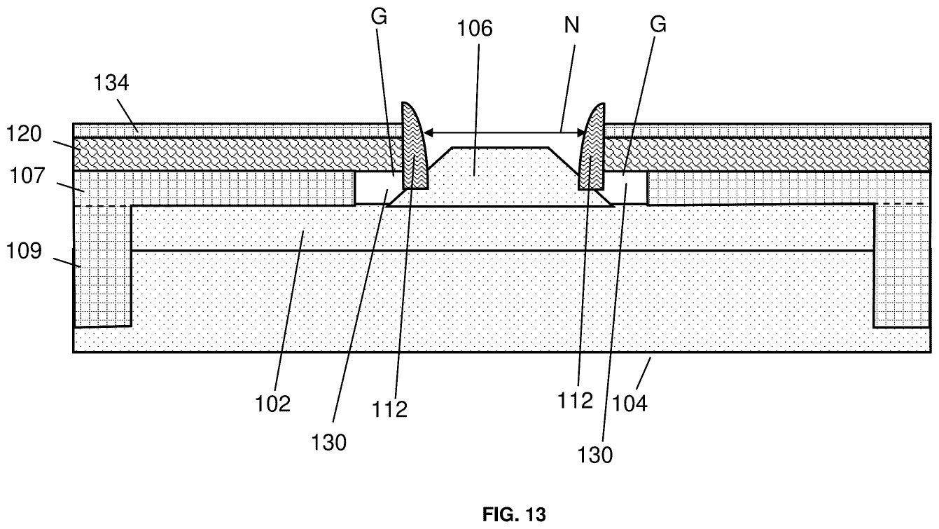

FIG. 12 depicts removing additional portions of first dielectric layer 107 beneath extrinsic base 120, and optionally, partial recessing of overlying dielectric layer 134 over extrinsic base 120. Additional selective etching of first dielectric layer 107 composition may produce undercut regions G beneath second dielectric layers 108. Undercut regions G, once formed, may enable air gaps (FIGS. 1-3) to be formed during subsequent processing to form collector 106 (FIGS. 1-3) of bipolar transistor 110. Undercut regions G may be formed from first dielectric layer 107 in a lower portion of opening N can be formed in first dielectric layer 107 using an isotropic etch process. In this case, the isotropic etch process can be selective for first dielectric layer 107 so that it stops at subcollector 102 and also so that it undercuts extrinsic base 120, due to their different compositions. Thus, a portion of overlying dielectric layer 134 remains intact over undercut region G (i.e., the removed areas of first dielectric layer 107.) FIG. 13 illustrates forming collector 106 within opening N and partially within undercut regions G. Collector 106 may be formed by epitaxial growth and doping of semiconductor material on subcollector 102 within opening N, as discussed with respect to other implementations. In the case of forming by epitaxial growth, collector 106 may have sidewall shapes dependent on the shape of first dielectric layer(s) 107, spacers 112, extrinsic base 120, the manner of growth implemented and/or the crystallographic orientation of subcollector 102 thereunder. Collector 106 may not completely horizontally fill opening N and undercut regions G because growth occurs primarily in an upward direction. Since spacers 112 protrude horizontally inward from first dielectric layer 107, extrinsic base 120, and overlying dielectric layer 134, portions of collector 106 may physically interface with spacer 112, thereby defining air gaps 130 between collector 106 and first dielectric layer 107. The height of collector 106 may be controlled, e.g., by controlling the amount of deposition time and/or etching back collector 106 material once it is formed. In an example, an upper surface of collector 106 is below an upper surface of extrinsic base 120 and located between spacers 112.

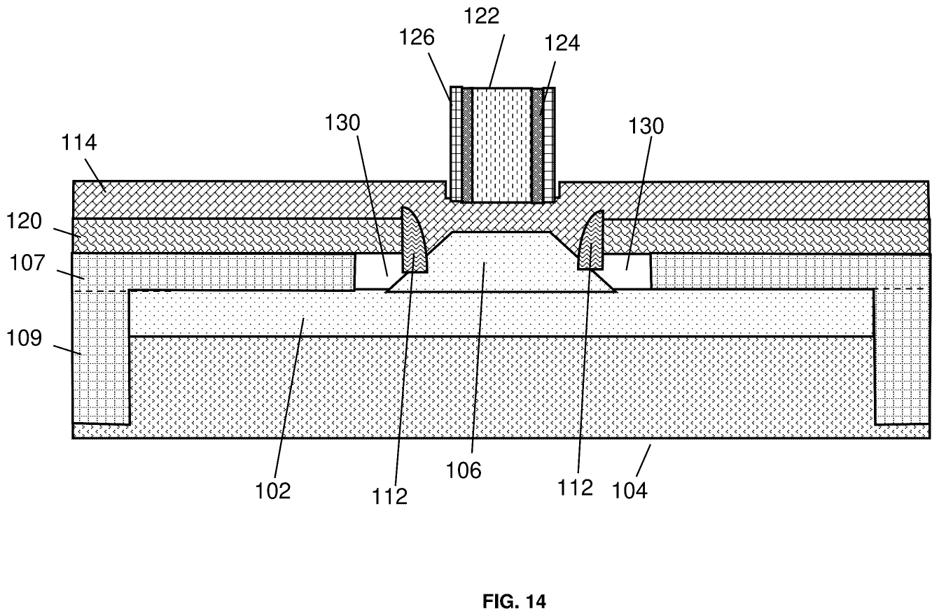

Referring to FIG. 14, further processing may include, e.g., forming intrinsic base 114 as a monocrystalline semiconductor material on collector 106. Intrinsic base 114 may be on collector 106 horizontally between spacers 112. Intrinsic base 114 also may extend horizontally outward over extrinsic base 120 and may extend to a predetermined height over extrinsic base 120. Intrinsic base 114 may be undoped or have an opposite doping type from collector 106, and in addition, may have a lower concentration of dopants therein. Collector 106 and/or intrinsic base 114 may be doped in situ, or alternatively, through implantation and/or other currently known or later developed doping techniques. The forming of intrinsic base 114 may begin only after collector 106 is at a predetermined height over subcollector 102 (e.g., where its upper surface is between spacers 112). In this configuration, semiconductor film 116 (FIGS. 1, 2, 6-9) may not be present. Additional processing may include, e.g., forming emitter 122 on intrinsic base 114. As noted elsewhere herein, emitter film 118 (FIGS. 1, 2, 8, 9) may be omitted in configurations where intrinsic base 114 overlies extrinsic base 120. Inner spacer 124 and outer spacer 126 may be formed alongside emitter 122 by conformal deposition, etching, and/or other processes discussed herein to form various insulator layers alongside semiconductor material.

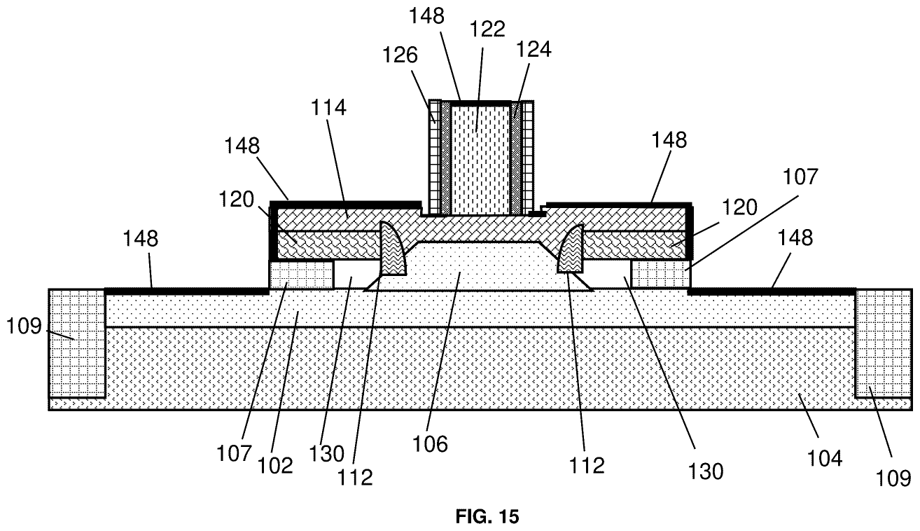

Referring to FIG. 15, methods of the disclosure may include removing horizontally outer portions of first dielectric layer 107, extrinsic base 120, and intrinsic base 114. Outer portions of first dielectric material 107, extrinsic base 120, overlying dielectric layer 134 (if still present), and intrinsic base 114 may be removed e.g., by forming a temporary masking material (not shown) over inner portions these materials and thereafter removing the temporary mask. This process also physically separates first dielectric layer 107 from TI(s) 109 thereunder. At this stage, semiconductor material within subcollector 102, intrinsic base 114, extrinsic base 120, and emitter 122 is exposed and thus susceptible to silicidation. Conductive material(s) may be selectively formed on semiconductor materials, annealed to cause migration of conductors into the semiconductor material, and the conductive material(s) thereafter can be removed to form silicide layers 148 as shown. Remaining processes to form structure 100 (e.g., as shown in FIG. 3) may include forming ILD 140 (FIG. 3) and contact(s) 142, 144, 146 therein.

Embodiments of the disclosure provide various technical and commercial advantages, examples of which are discussed herein. Embodiments of the disclosure assist fabrication tools and facilities in further decreasing the scale of individual bipolar transistors 110 at desired performance levels, e.g., using spacer(s) 112 to limit or control the height of collector 106 in bipolar transistor 110. Furthermore, emitter film 118 may be included on semiconductor film 116 to further customize the shape and size of the emitter material(s) in bipolar transistor 110 without significantly affecting the size and/or processing techniques of bipolar transistor 110. These structural aspects of bipolar transistor 110 allow fabricators to achieve the benefits of vertical scaling more easily in vertical heterojunction bipolar transistor architectures. Furthermore, spacers 112 provide the related benefit of allowing air gap 130 and, optionally, upper air gap 132 to be formed to further isolate extrinsic base(s) 120 from the active materials in collector 106. This additional separation, in turn, may reduce or eliminate parasitic capacitive junctions and thus may improve various electrical properties such as increasing the threshold frequency (i.e., the signal frequency magnitude where transistor gain begins to decrease) of bipolar transistor 110 during operation.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/-10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A structure comprising:
a first isolation layer on a subcollector, wherein a first air gap is between the first isolation layer and a collector of a bipolar transistor (BT);
a second isolation layer on the first isolation layer and adjacent an intrinsic base of the BT; and
a third isolation layer on the second isolation layer, vertically between the second isolation layer and an extrinsic base of the BT, wherein a second air gap is adjacent the third isolation layer and below the extrinsic base, and wherein the second isolation layer defines a physical boundary between the first air gap and the second air gap.

2. The structure of claim 1, wherein the second isolation layer is adjacent a lower portion of the intrinsic base of the BT, and wherein the second air gap is adjacent an upper portion of the intrinsic base of the BT.

3. The structure of claim 1, wherein the first isolation layer and the third isolation layer each include a same material.

4. The structure of claim 1, wherein the first isolation layer, the second isolation layer, and the third isolation layer form an oxide-nitride-oxide (ONO) stack.

5. (canceled)

6. The structure of claim 1, wherein the first air gap is one of a pair of first air gaps each adjacent a sidewall of the collector, and wherein the second air gap is one of a pair of second air gaps each adjacent a sidewall of the intrinsic base.

7. The structure of claim 1, wherein the BT is a vertically-oriented heterojunction bipolar transistor.

8. A structure comprising:
a bipolar transistor (BT) including a subcollector, a collector on the subcollector, an intrinsic base on the collector, an extrinsic base on a first portion of the intrinsic base, and an emitter on a second portion of the intrinsic base; and
an isolation stack adjacent the BT, the isolation stack including:
a first isolation layer on the subcollector, wherein a first air gap is between the first isolation layer and the collector, and wherein a portion of the first air gap is above a portion of the collector;
a second isolation layer on the first isolation layer and adjacent the intrinsic base of the BT; and
a third isolation layer on the second isolation layer, vertically between the second isolation layer and the extrinsic base of the BT, wherein a second air gap is adjacent the third isolation layer and below the extrinsic base, wherein the second isolation layer defines a physical boundary between the first air gap and the second air gap.

9. The structure of claim 8, wherein the second isolation layer of the isolation stack is adjacent a lower portion of the intrinsic base of the BT, and wherein the second air gap is adjacent an upper portion of the intrinsic base of the BT.

10. The structure of claim 8, wherein the first isolation layer and the third isolation layer each include a same material.

11. The structure of claim 8, wherein the first isolation layer, the second isolation layer, and the third isolation layer form an oxide-nitride-oxide (ONO) stack.

12. (canceled)

13. The structure of claim 8, wherein the emitter of the BT is one of a plurality of emitters on the second portion of the intrinsic base.

14. A method comprising:
forming a first isolation layer on a subcollector, wherein a first air gap is between the first isolation layer and a collector of a bipolar transistor (BT);
forming a second isolation layer on the first isolation layer and adjacent an intrinsic base of the BT; and
forming a third isolation layer on the second isolation layer, vertically between the second isolation layer and an extrinsic base of the BT, wherein a second air gap is adjacent the third isolation layer and below the extrinsic base, wherein forming the second isolation layer defines a physical boundary between the first air gap and the second air gap.

15. The method of claim 14, wherein the second isolation layer is adjacent a lower portion of the intrinsic base of the BT, and wherein the second air gap is adjacent an upper portion of the intrinsic base of the BT.

16. The method of claim 14, wherein the first isolation layer and the third isolation layer each include a same material.

17. The method of claim 14, wherein forming the first isolation layer, the second isolation layer, and the third isolation layer includes forming an oxide-nitride-oxide (ONO) stack.

18. (canceled)

19. The method of claim 14, wherein the first air gap is one of a pair of first air gaps each adjacent a sidewall of the collector, and wherein the second air gap is one of a pair of second air gaps each adjacent a sidewall of the intrinsic base.

20. The method of claim 14, further comprising forming the BT as a vertically-oriented heterojunction bipolar transistor on the subcollector.
